(19) United States
(12) Patent Application Publication
(10) Pub. No.: US 2003/0227062 A1
(43) Pub. Date: Dec. 11, 2003

(54) Semiconductor device and method of fabricating the same

(76) Inventors: Masatada Horiuchi, Koganei (JP); Kazuhiro Ohnishi, Kodaira (JP); Akio Shima, Hino (JP); Takashi Takahama, Higashimurayama (JP); Masakazu Kawano, Mitaka (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/455,441

(22) Filed: Jun. 6, 2003

(30) Foreign Application Priority Data
Jun. 7, 2002 (JP) P2002-166457

(51) Int. Cl. H01L 29/76; H01L 29/94

(52) U.S. Cl. 257/382

(57) ABSTRACT

Source-drain diffusion regions of a shallow junction and a stacked metal silicide film structure of a low resistance in a miniaturized MIS transistor are to be attained while ensuring high reliability. The concentration of an impurity (As, P, In, Sb) in surface areas of source-drain diffusion regions (6, 7) is set to a value of not smaller than 5×10²¹/cm³. Alternatively, an alloy film of germanium and silicon containing not less than 20% of germanium, or germanium film, is formed on surface areas of the source-drain diffusion regions (6, 7).

### BACKGROUND OF THE INVENTION

1. Field of the Invention

The present invention relates to a semiconductor device. In particular, the present invention is concerned with decreasing leakage current, attaining a high driving current, and attaining a high-speed operation, in an ultra-miniaturized MIS type field effect transistor.

2. Related Arts

An insulated gate field effect transistor which constitutes an ultra-high density semiconductor device, particularly an MIS type field effect transistor (hereinafter referred to simply as “MIS”), has become more and more miniaturized in accordance with the scaling law, and an ultra-miniaturized MIS having a gate length of not larger than 15 nm has also been made public. In such an ultra-miniaturized MIS, with miniaturization of the gate length and with use of a low supplied voltage, source and drain diffusion junctions are tend to be shallower in order to decrease the punch through current. With such shallow-junction of diffusion regions, a sheet resistance of the diffusion layers increases abruptly. And an attempt has been made to form additional deep source and drain diffusion regions and thereby make a series resistance as low as possible. However, as the gate length becomes more and more miniaturized, a punch-through current path between the additional deep source and drain diffusion regions is becoming unignorable and is obstructing the attainment of low power consumption. For solving the problems involved in such deep source and drain diffusion layers, there has been proposed, for example, such a structure as is disclosed in Japanese Patent Laid Open No. 2001-127291 (FIG. 2) in which silicon or a silicided metal film is stacked on source and drain regions. In FIG. 2, a single crystal silicon layer 91 is stacked on each of source and drain diffusion regions 106, 107 by a selective epitaxial method, followed by implantation of an impurity for source and drain and subsequent metal-silicidation, to constitute regions 92. The source and drain diffusion regions are partially formed by diffusion from gate side wall insulators 51 which are highly doped with an impurity. According to the conventional technique, including the one disclosed in the foregoing prior art literature, the thickness of the silicided metal film stacked on the source and drain diffusion regions is determined by controlling the thickness of a refractory metal film deposited on each of the single crystal silicon layers 91. It is very difficult to control the film thickness by adjusting the siliciding thermal annealing time or temperature.

As another method for stacking a silicided metal film on the source and drain diffusion regions there may be adopted such a method as is disclosed in Japanese Patent Laid Open No. 2001-345442 in which a silicided metal film or a metallic film is desposited directly by a sputtering method for example. However, a silicided metal film based on physical or chemical deposition is difficult to have a composition ratio which is stable thermo-equilibriumwise, causing in a subsequent thermal treatment step a change in composition ratio, i.e., a change in resistance value, or a problem of further prosecution of reaction with an underlying substrate. For this reason it is not suitable to apply this method to an ultra-miniaturized MIS for which are required source and drain regions having an ultra-shallow junction depth of not larger than 20 nm.

Thus subject matter of the present invention is to simultaneously attain all of such high performance conditions as low leakage current, high current drive and low stray capacitance of an ultra-miniaturized MIS for which are required source and drain diffusion regions having an ultra-shallow junction depth of not larger than 20 nm. It is the first object of the present invention to fundamentally solve the problem that in the existing MIS structure, deep source and drain regions used together with shallow-junction source and drain diffusion regions (usually called extension) become closer in their spacing with miniaturization of gate electrodes, and the presence of a punch-through current flowing directly through the deep source and drain regions, i.e., an increase of leakage current, becomes unignorable. The punch-through current can be decreased by increasing the impurity concentration of the substrate, but also in an MIS having a gate length of 60 nm a maximum substrate impurity concentration already reaches 3×10¹⁸/cm³, and a further increase of the impurity concentration will result in an increase of both Zener tunnel current and stray capacitance.

It is the second object of the present invention to solve a problem involved in a known process wherein a conductive film, especially a silicided metal film, stacked on a main surface of a semiconductor substrate is allowed to play the role of the foregoing deep source and drain diffusion regions. More particularly, at the time of converting a semiconductor film such as silicon film which has been left selectively on ultra-shallow junction source and drain diffusion regions into a silicided metal film, it is required to strictly control the thickness of the silicided metal film, or else the silicided metal film may break through the ultra-shallow junction, which may lead to a critical junction destruction defect. The present invention intends to control the silicidation reaction between the metal film and the silicon film so as to afford a silicided metal film having a desired thickness without depending on the metal film thickness.

According to the source-drain shallow junction forming technique based on ion implantation and a subsequent rapid high temperature thermal annealing step, which technique is widely applied to the current MIS fabrication technique, a limit is being encountered in promoting a shallow junction required in the miniaturization scaling law for MIS. It is a further object of the present invention to fundamentally break down this situation and implement diffusion regions of a low resistance despite an ultra-shallow junction. More specifically, the present invention intends to realize ultra-shallow source and drain regions having a box-shaped impurity profile also in a lateral direction without causing an increase of junction depth which is due to thermal diffusion of ion-implanted regions. In the present invention device having the box-shaped impurity profile, the solid solubility of impurity is raised and the activation rate is increased to a great extent. In the present invention it is intended to realize box-shaped heavily doped diffusion regions of a low resistance at a shallow junction and attain both a lowering of source-drain series resistance and suppression of the punch-through current. In this connection it is also intended in the present invention to optimize a lateral diffusion of a low concentration in source and drain diffusion regions because a lateral diffusion of such low concentration regions acts to induce a punch-through phenomenon. That is, it is intended to suppress a short channel effect in a miniaturized MIS and thereby provide a miniaturized MIS of high performance wherein a threshold voltage value varies less effective to a change in gate length and a high current output can be obtained even at a low supply voltage.

### SUMMARY OF THE INVENTION

According to the present invention, in forming ultra-shallow source and drain diffusion regions in a main surface of a semiconductor substrate using a gate electrode as an implantation stopping mask, ion implantation is carried out at an impurity concentration of 5×10¹⁵/cm² or more which is five times or more as high as that in the prior art, using low acceleration energy, to form a region having a maximum impurity concentration of 1×10²¹/cm³ or more. The method for implanting a high concentration impurity is not limited to ion implantation, but there may be adopted another known method, e.g., plasma injection, chemical vapor deposition, or physical deposition. Even if any of these known methods is used, there will arise no problem.

For activating all the impurity quantity of the above value it is preferable to conduct a high-temperature thermal treatment at a temperature of 1200° C. or higher, but the conventional rapid thermal annealing in one second or less ultra-rapid thermal annealing called spike thermal annealing not longer than one second involves the problem that the junction depth becomes too deep. For this reason there is used laser irradiation in which the heating time is several tenth nanoseconds and is thus an ultra-ultra short time. High concentration ion implantation has a characteristic such that a single crystal semiconductor substrate changes to be amorphized, but an absorption coefficient of an amorphous layer for laser beam is large in comparison with a single crystal region, whereby only the amorphous layer, i.e., the layer formed by the high concentration ion implantation, can be melted and liquidized. In a liquidized silicon region wherein the melted and liquidized region completes crystal recovery from liquid phase by solidizing within several nanoseconds after the end of several tenth nanosecond laser irradiation, it is known that the diffusion rate of impurity is eight orders or more higher than in solid phase. In the case where the melting and liquidizing time is as extremely short as several tenth nanoseconds, it is possible to form a state in which the rise in temperature of the substrate region located just under the melted region can be ignored from a balance with heat dissipation and from the standpoint of impurity diffusion. Consequently, the impurity in the solidized region from liquid phase presents a substantially flat box-shaped impurity profile, and in the region just under the melted region there is maintained an impurity profile which is nearly equal to that before thermal treatment. It is preferable that the junction depth obtained in the ultra-miniaturized MIS according to the present invention be not larger than 20 nm. As a method for melting only the foregoing amorphized layer there is adopted laser irradiation using a gas excitation pulse laser such as XeCl or KrF. The wavelength of the former is 308 nm and that of the latter is 248 nm. There may be adopted a solid laser having a wavelength of 1064 nm, which is called YAG laser. According to the conventional rapid thermal annealing, a sheet resistance of P⁺N junction is 1300 Ω/□ even at a junction depth of 30 nm, while a sheet resistance of P⁺N junction based on melting and recrystallization of an ion-implanted amorphous layer by laser irradiation is 200 Ω/□ even at a 50% shallower junction depth, i.e., 20 nm, and can thus be decreased to a remarkable extent. Thus, there can be made a great contribution to decreasing the series resistance of the ultra-miniaturized MIS, i.e., the attainment of a high current. The activating thermal treatment for the implanted impurity is not limited to laser irradiation, but there may be adopted any other thermal treatment method if only the method adopted permits the formation of single-crystallized, ultra-shallow source and drain diffusion regions having a high concentration (1×10²¹/cm³ or more) and having a box shaped impurity profile.

In the present invention, after formation of the source and drain diffusion regions with an ultra-shallow junction depth, an insulating film is placed on side walls of the gate electrode and a main portion of the single crystal source-drain diffusion regions is exposed. Thereafter, a silicon film is placed selectively on the exposed single crystal source-drain diffusion regions. The thickness of the silicon film was set at about 30 nm. For allowing the silicon film to remain selectively there may be adopted a known selective epitaxial method to let a single crystal silicon film to grow or a solid phase epitaxial method involving deposition of an amorphous silicon film throughout a main surface and subsequent low temperature treatment at about 600° C. In growing a single crystal silicon film in accordance with the known selective epitaxial method there exists a crystal growth-inhibit region (called a facet) at a boundary region of the gate side wall insulator or the device isolation insulator, but in the present invention there arises no problem even if the facet remains existent. This is for the reason to be stated later. According to the aforesaid solid phase epitaxial method using a low temperature treatment, the silicon film is allowed to remain in the following manner. Exposed single crystal source-drain diffusion regions play a role of growth nucleus, a single crystallization or polycrystallization proceeds selectively on the exposed single crystal source-drain diffusion regions. Crystalgrowth slows down upon contact with an insulator region such as the gate side wall insulator. The silicon film on the side wall insulator present in the amorphous state. This film can be removed selectively with hot phosphoric acid for example. As another method for allowing the silicon film to remain selectively on the source-drain diffusion regions there may be adopted a method wherein an upward convex region such as the gate electrode is used as a polish stopping mask and the portion located on the upward convex region of a conductive semiconductor film such as silicon film deposited on the whole surface is removed selectively by chemino-mechanical polishing. It is optional whether the conductive semiconductor film such as silicon film referred to above is to be doped with the same conductive impurity as the impurity which constitutes the source-drain diffusion regions, although the reason therefor will be stated later. In case of adding such an impurity, the amount of the impurity is preferably 5×10²⁰/cm³ as maximum or less.

After the conductive semiconductor film such as silicon film has been remained selectively on the source-drain diffusion regions, a refractory metal film is deposited throughout the whole surface by sputtering or a chemical vapor reaction for example, followed by siliciding thermal annealing. As the material of the refractory metal film there may be used any of those so far used as the materials of silicided metal films such as Co, Ni, Ti, Ta, W, and Mo. In the known method for fabricating a silicided metal film, it is absolutely necessary that the thickness of a refractory metal film which is deposited be controlled strictly in order to obtain a desired film thickness. Controlling the thickness of a refractory metal film in terms of siliciding temperature or time in a deposited state of the refractory metal film at a thickness above the desired thickness is impossible in effect due to the influence of crystallinity of the underlying silicon film, for example because of a difference in the siliciding reaction rate due to the presence of a grain boundary. In an ultra-miniaturized MIS it is desired that the thickness of the silicided metal film on source-drain diffusion regions be 25 nm or more. In the case of a refractory metal film, e.g., Co film, the aforesaid film thickness of 25 nm is not guaranteed unless a strict control is made to a film thickness of 7 nm. It is as noted earlier that a stacked structure onto source-drain diffusion regions is essential to an ultra-miniaturized MIS not having deep source-drain diffusion regions. But the thickness control for the silicided metal film in the stacked structure is closely related to the depth of an ultra-shallow source-drain junction and also to the thickness control for each of stacked silicon films having a homogeneous and uniform film thickness, and there result specialization and high cost of the manufacturing process, as well as a great decrease of the process yield.

In the present invention, a refractory metal film is deposited at a thickness of not smaller than the thickness required for forming a desired thickness of a silicided metal film and the manufacturing process is proceeded in accordance with the conventional siliciding thermal annealing. The present invention is based on a novel phenomenon which has been found out in the course of evaluating the dependency on the kind of a substrate impurity and impurity concentration in connection with a metal siliciding reaction. The dependence of a metal siliciding reaction on the kind of a substrate impurity and impurity concentration has heretofore been known and it has been known that there is no dependency in a concentration range of below 10²⁰/cm³. The present invention is based particularly on the fact that the activation of an ultra-high concentration impurity of 1×10²¹/cm³ or higher, which had been impracticable from the standpoint of solid solubility in case of performing an activating thermal annealing for an ion implanted layer using the known rapid high-temperature thermal annealing method, became possible by a laser irradiation method. Having re-evaluated the aforesaid dependency on the basis of this fact and with respect to an ultra-high concentration region, the present inventor found out the following new phenomenon.

Arsenic ions were implanted into a main surface region of a single crystal silicon substrate by an ion implantation method using an acceleration energy of 5 keV and in doses of 0, 1×10¹⁴/cm², 1×10¹⁵/cm², 2×10¹⁵/cm², 5×10¹⁵/cm², 1×10¹⁶/cm², 2×10¹⁶/cm², and 5×10¹⁶/cm², then the ion-implanted regions were melted by XeCl laser irradiation and re-crystallization was performed. For all of the samples, a 30 nm thick silicon film was formed selectively and a 10 nm thick cobalt film was deposited on the surface of the silicon film by sputtering, followed by rapid thermal annealing at 500° C. for 1 minute and a subsequent treatment for forming cobalt silicide film on the surface of the selectively formed silicon film, thereafter unreacted cobalt film was removed selectively using a mixed solution of ammonium and a hydrogen peroxide solution. In this state, each sample was cleaved and the remaining cobalt silicide film was checked for thickness using a high-resolution scanning electron microscope (resolution: about 1 nm). As a result, the cobalt silicide film thickness in each of the samples not more than 1×10¹⁵/cm² in dose was approximately 35 nm, while that in the sample of 2×10¹⁵/cm² in dose was about 32 nm, and that in the samples of 5×10¹⁵/cm² or more in terms of dose was 30 nm in the resolution range of the electron microscope, with no change from the thickness of the selectively formed silicon film, and it was impossible to confirm the presence of any cobalt silicide film reaching the semiconductor substrate region underlying the selectively formed silicon film. The same experiment was conducted also with respect to ion implantation of phosphorus (P), boron (B), indium (In), and antimony (Sb), and studies and evaluations were conducted. As to the sample implanted with boron ions, there was scarcely recognized any dependency of the thickness of cobalt silicide film formed on the dose of boron, and the film thickness was found to be approximately 35 nm. As to the dependency of the P, In and Sb ion implanted samples on dose, it turned out that does at which the presence of cobalt silicide film could no longer be confirmed in the semiconductor substrate region underlying the selectively formed silicon film were not less than 1×10¹⁶/cm² in the case of P ions and not less than 5×10¹⁵/cm² in the case of In and Sb ions.

In the As ion implanted sample, a maximum impurity concentration in the sample of 5×10¹⁵/cm² in dose was found to be about 5×10²¹/cm³ according to secondary ion mass spectroscopy. The above experimental fact indicates that the metal siliciding reaction is extremely suppressed in the region where such an impurity as As is present at an ultra-high concentration of not lower than about 5×10²¹/cm³ and that the siliciding reaction proceeds with little dependence on concentration up to such a high concentration layer as has so far been used for source and drain diffusion regions, i.e., up to about 1×10²¹/cm³. If the above new phenomenon is applied to a stacked source-drain structure of an ultra-miniaturized MIS having an ultra-shallow junction, only the stacked semiconductor film portions can be selectively metal-silicided independently of, for example, non-uniformity in thickness of the stacked semiconductor film portions. More particularly, in the conventional source-drain stack structure, a measure based on a complicated fabricating process has been taken against local thinning in a boundary region with an insulator called facet which is based on the selective epitaxial method. But according to the present invention, only a stacked semiconductor layer can be metal-silicided almost completely without the need of correction with respect to non-uniformity of the stacked semiconductor layer, whereby the fabrication process can be simplified and miniaturized to a great extent. Further, since the metal siliciding reaction is suppressed as to an ultra-shallow source-drain junction of not more than 20 nm in depth, it is possible to completely prevent junction penetration of metal or metal silicide. Consequently, it is possible to omit the formation of source-drain diffusion regions having a deep junction which have so far been used for preventing the junction penetration of a metal silicide in MIS. This means that twice region establishing mask processing steps and twice ion implantation steps for deep source-drain diffusion regions in N-channel MIS (“NMIS” hereinafter) and P-channel MIS (“PMIS” hereinafter) in a so-called complementary MIS (“CMIS” hereinafter) fabrication process can be omitted. This process simplification permits reduction of the process cost. At the same time, due to the omission of deep source-drain diffusion regions, it is possible to eliminate a punch-through current flowing through a deep substrate portion or a leakage current component based on Zener tunnel current, whereby it is possible to attain a low power consumption. Additionally, since a decrease of series resistance can also be attained due to source-drain metal silicidation, it is possible to attain a high current high-speed operation. The semiconductor device according to the present invention can be fabricated by carrying out the selective metal silicidation of a source-drain stacked semiconductor layer under essentially extremely mild fabrication conditions and subsequently carrying out a metal interlayer passivation step, a metal-to-metal connection forming step, and a metallization step in accordance with conventional methods.

The metal siliciding reaction suppressing phenomenon for the semiconductor film can also be applied to the source-drain stack structure of the miniaturized MIS with use of a second method. In a searching experiment for silicidation suppressing impurities associated with the semiconductor film metal-siliciding reaction, the present inventor has continued a further study also about other impurities than those referred to above and found out that a high concentration germanium (Ge) also exhibits a silicidation suppressing effect. On the basis of this experiment result there was fabricated an ultra-miniaturized MIS of a source-drain stacked silicided metal film structure having an ultra-shallow source-drain junction. In this second method, the dose used in forming the above ultra-shallow source-drain junction was set at an impurity concentration equal to that in the conventional structure, i.e., 1 to 2×10¹⁵/cm² or less. Where required, however, the dose may be set to a still higher concentration. Even in this case there will arise no problem. Subsequently, there was performed an activating thermal annealing for the implanted impurity and a gate side wall insulator was formed in accordance with the foregoing first method. By a chemical vapor reaction, a Ge-doped Si film-Si film stack layer having a thickness of not larger than 10 nm was allowed to remain selectively in an exposed main surface portion of source-drain diffusion regions of a single crystal. In this case, samples were produced while changing the addition ratio of Ge from 10% to 100% in increments of 10%. As the above method for forming a stacked semiconductor layer there may be adopted a physical deposition method such as the foregoing sputtering method. The thickness of the upper Si layer was set at about 30 nm. Ion implantation for doping the selectively remaining stacked semiconductor layer with a source-drain constituting impurity was carried out at a dose condition of 5×10¹⁴/cm². Thereafter, a 10 nm thick Co film was formed by sputtering throughout the whole surface including the selectively remaining stacked semiconductor layer. In this case, there may adopted a method based on chemical vapor reaction. The ion implantation may be omitted if desired. Next, a rapid thermal annealing is performed at 500° C. for one minute to form cobalt silicide film on the selectively remaining stacked semiconductor layer, and subsequently unreacted Co film was removed selectively using a mixed solution comprising ammonium and a hydrogen peroxide solution. In this state each sample was cleaved and the remaining cobalt silicide film was measured for thickness using a high resolution scanning electron microscope. As a result, the thickness of the cobalt silicide film in the 10%-Ge sample was approximately 35 nm, while the thickness in the 20%-Ge sample was about 32 nm and thus the metal silicidation of Ge film was substantially suppressed. In the higher-Ge samples, the cobalt silicide film thickness was 30 nm equal to that of the deposited upper Si film in the resolution range of the electron microscope, and as to the Ge-doped lower Si film, it was impossible to confirm a silicidation reaction. This fact indicates that a mixed crystal SiGe film doped with 20% or more Ge has a function of suppressing the metal siliciding reaction. Therefore, by using a mixed crystal SiGe film as a metal silicidation suppressing film and metal-siliciding only an overlying semiconductor film, it is possible to completely eliminate the influence of the metal siliciding reaction on the underlying semiconductor substrate. In the conventional source-drain stack structure, a measure based on a complicated fabrication process has been taken against a local thinning of film in a boundary region with the insulator called facet which is attributable to the selective epitaxial method. But in accordance with the second method in the present invention, only the stacked semiconductor layer can be metal-silicided almost completely without the need of any correction of non-uniformity in thickness of the semiconductor layer, thus permitting simplification and miniaturization of the fabrication process to a great extent. Further, the bad influence of the metal siliciding reaction is completely suppressed also for a source-drain junction of an ultra-shallow junction having a depth of not larger than 20 nm, so that the junction penetration metal or metal silicide can be prevented completely. Thus, the formation of source-drain regions having a deep junction so far used for preventing the junction penetration of a metal silicide in the conventional MIS can be omitted. This means that twice region establishing masking steps and twice ion implanting steps carried out to form deep source-drain diffusion regions in each of NMIS and PMIS in the fabrication process of CMIS can be omitted. Therefore, the process cost can be reduced by process simplification. At the same time, since the formation of deep source-drain diffusion regions is omitted, the leakage current based on a punch-through current flowing through a deep substrate portion or on Zener tunnel current can be eliminated, thus permitting the attainment of low power consumption. Besides, since the decrease of series resistance can also be attained by source-drain metal silicidation, it is possible to attain a high-current high-speed operation of MIS. The semiconductor device based on the second method in the present invention can be completed by first performing the selective metal siliciding process for a source-drain stacked semiconductor layer under essentially extremely mild fabrication conditions and then performing a metal interlayer passivation fabricating step, a metal-to-metal connection fabricating step and a metallization step in accordance with known methods.

### BRIEF DESCRIPTION OF THE DRAWINGS

FIG. 1 is a sectional view of a completed semiconductor device according to a first embodiment of the present invention;

FIG. 2 is a sectional view of a conventional MIS transistor;

FIG. 3 is a sectional view showing a fabrication step for the semiconductor device according to the first embodiment;

FIG. 4 is a sectional view showing a fabrication step for the semiconductor device according to the first embodiment;

FIG. 5 is a sectional view showing a fabrication step for the semiconductor device according to the first embodiment;

FIG. 6 is a sectional view showing a fabrication step for a semiconductor device according to a second embodiment of the present invention;

FIG. 7 is a sectional view showing a fabrication step for the semiconductor device according to the second embodiment;

FIG. 8 is a sectional view showing a fabrication step for the semiconductor device according to the second embodiment;

FIG. 9 is a sectional view showing a completed state of the semiconductor device according to the second embodiment of the present invention;

FIG. 10 is a sectional view showing a fabrication step for a semiconductor device according to a third embodiment of the present invention;

FIG. 11 is a sectional view showing a fabrication step for the semiconductor device according to the third embodiment;

FIG. 12 is a sectional view showing a completed state of the semiconductor device according to the third embodiment;

FIG. 13 is a sectional view showing a fabrication step for a semiconductor device according to a fourth embodiment of the present invention;

FIG. 14 is a sectional view showing a fabrication step for the semiconductor device according to the fourth embodiment of the present invention;

FIG. 15 is a sectional view showing a completed state of the semiconductor device according to the fourth embodiment of the present invention;

FIG. 16 is a sectional view showing a fabrication step for a semiconductor device according to a fifth embodiment of the present invention;

FIG. 17 is a sectional view showing a fabrication step for the semiconductor device according to the fifth embodiment of the present invention; and

FIG. 18 is a sectional view showing a completed state of the semiconductor device according to the fifth embodiment.

### DETAILED DESCRIPTION OF THE PREFERRED EMBODIMENTS

When required for convenience' sake, the following embodiments will be described in a divided manner into plural sections or embodiments, but unless otherwise mentioned, they are not unrelated to each other, but are in a relation such that one is a modification, a description of details, or a supplementary explanation, of part or the whole of the other.

In the following embodiments, when reference is made to the number of elements (including the number, numerical value, quantity, and range), no limitation is made to the number referred to, but numerals above and below the number referred to may be used unless otherwise specified and except the case where it is basically evident that limitation is made to the number referred to.

In the following embodiments, moreover, it goes without saying that their components (including constituent steps) are not always essential unless otherwise mentioned and except the case where they are considered essential basically clearly.

Likewise, in the following embodiments, it is to be understood that when reference is made to the shape and positional relation of a component, those substantially similar or closely similar thereto are also included unless otherwise mentioned and except the case where the answer is negative basically clearly. This is also true of the foregoing numerical value and range.

In all of the drawings for illustrating the embodiments, portions having the same functions are identified by like reference numerals, and repeated explanations thereof will be omitted.

In the following embodiments, MIS•FET (Metal Insulator Semiconductor Field Effect Transistor) which represents field effect transistors is abbreviated to MIS, a p-channel MIS•FET is abbreviated to PMIS, and an n-channel MIS•FET is abbreviated to NMIS. MOS•FET is a transistor whose gate insulator is formed by a silicon oxide film (e.g., SiO₂), and it is assumed to be included in a more specific concept of MIS.

Embodiments of the present invention will be described in detail hereinunder with reference to the accompanying drawings. It goes without saying that the material, conductivity type and fabrication conditions of various components are not limited to those described in the embodiments, but that various modifications may be made.

### First Embodiment

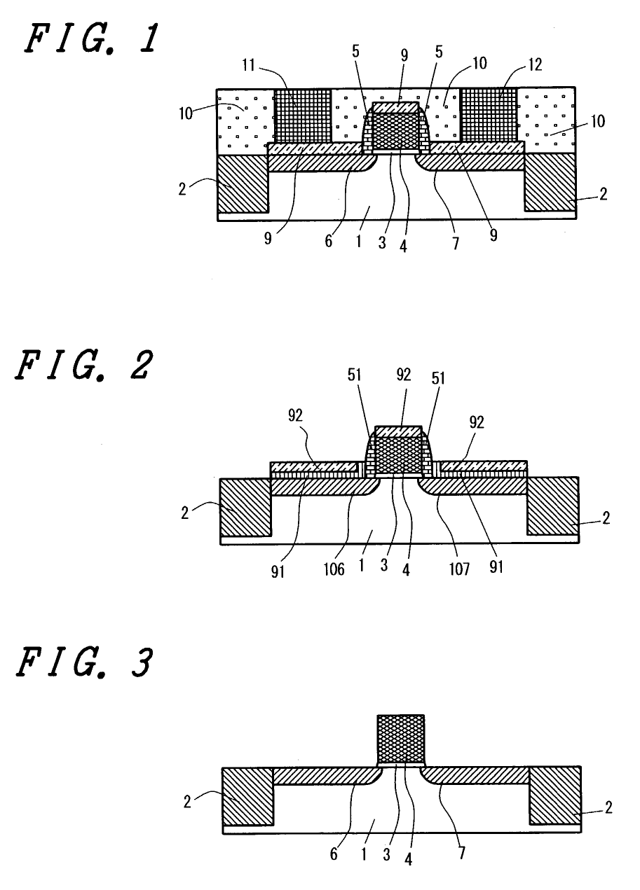

FIG. 1 is a sectional view of a completed NMIS which constitutes a semiconductor device according to a first embodiment of the present invention and FIGS. 3 to 5 are sectional views showing fabrication steps for the NMIS. A semiconductor substrate 1 of a single crystal Si having a plane direction (100), a conductivity type of P and a diameter of 20 cm was formed with device isolation insulators 2 for defining an active region and was subjected to an implanting and driving thermal treatment of conductive type P ions for substrate concentration adjustment and further to an ion implantation and activating thermal treatment for threshold voltage adjustment in accordance with known methods. Thereafter, a thermally oxidized film having a thickness of 1.8 nm was formed and its surface was nitridized to form a nitride film of 0.2 nm as a gate insulator 3 in a stacked state. The nitride film is larger in relative permittivity than the thermally oxidized Si film and an optical thickness thereof electrically equivalent to the thermally oxidized Si film corresponds to about two-fold thickness. Next, a polycrystalline Si film 4 heavily doped with P was deposited on the gate insulator 3 to a thickness of 100 nm by a chemical vapor deposition method, followed by patterning of the polycrystalline Si film 4 by lithography to form a gate electrode having a length of 50 nm. In this state, using the gate electrode 4 as an implantation stopping mask, As ions were implanted under the conditions of acceleration energy 2 keV and dose 5×10¹⁵/cm². As a result of the ion implantation under the above conditions, the region of not less than 1×10¹⁹/cm³ in terms of impurity concentration was amorphized up to a depth of about 10 nm from a main surface of the semiconductor substrate. The ion implantation step was followed by an implanted ion activating thermal treatment to form ultra-shallow source diffusion region 6 and drain diffusion region 7. The activating treatment was carried out by the irradiation of a laser beam using an XeCl gas laser under the conditions of wavelength 308 nm, half maximum full-width of pulse 30 nanoseconds, and energy density 0.75 J/cm². The irradiation was only one-shot irradiation, but in overall irradiation, because of an irradiation area of 3×3 mm², the irradiation was carried out without superimposition of regions not more than 95% in maximum energy density. With the above laser beam irradiation, the amorphous layer was melted in an instant and was then re-crystallized. In the melting process, boron as impurity was re-distributed so as to provide a uniform concentration of about 5×10²¹/cm³ in the melting region and its thickness was found to be about 10 nm as a result of impurity profile measurement in the depth direction of the semiconductor substrate which measurement was conducted by secondary ion mass spectroscopy. The method of the above activating thermal treatment is not limited to the irradiation laser beam, but may be done by the conventional rapid high-temperature thermal annealing. Further, the device used for the laser irradiation is not limited to the XeCl gas laser, but may be another gas laser, e.g., a KrF gas laser of a wavelength of 248 nm or a YAG solid laser of a wavelength of 1064 nm. In an activating thermal treatment using a YAG laser of a wavelength of 1064 nm, the semiconductor substrate is coated throughout the whole surface thereof with an auxiliary film for absorbing laser beam and thus the ion implantation layer is subjected to the activating thermal treatment in an indirect manner, but there is no essential difference. (FIG. 3)

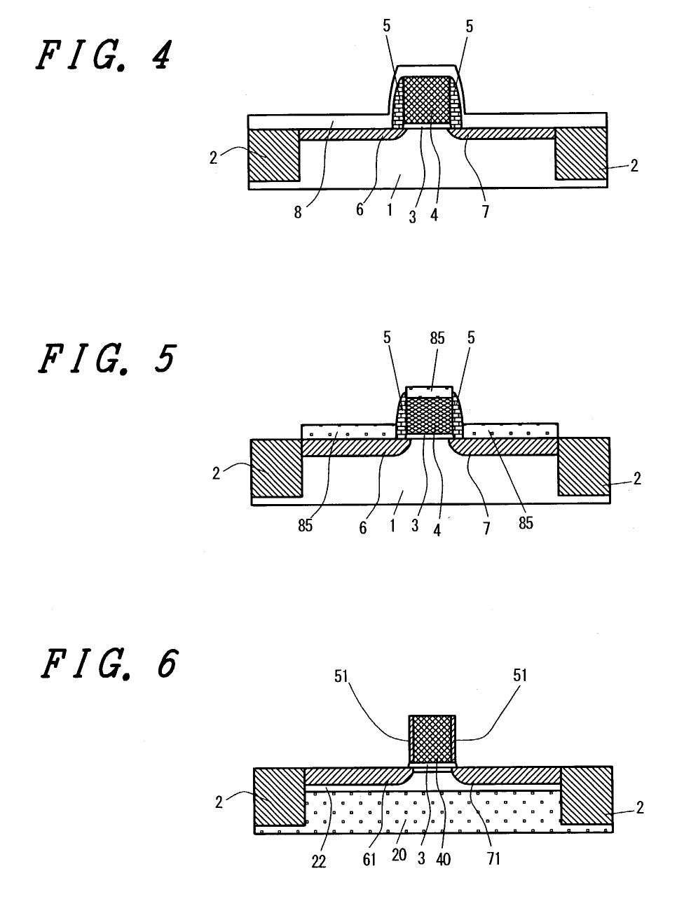

In the state of FIG. 3, a Silicon oxide film having a thickness of 20 nm is deposited on the whole surface at a low temperature of 400° C. by a plasma assist deposition method and then anisotropic etching was performed so that the oxide film was allowed to remain selectively on gate side walls, to form gate side wall insulators 5. In this state, an amorphous Si film 8 was deposited on the whole surface at a maximum thickness of 30 nm by a long throw sputtering method. In the regions (i.e., gate side wall regions) substantially parallel to the flying direction of sputter particles, the deposited film formed by the above long throw sputtering method is deposited at a thickness of only one tenth or less of that of the film deposited in the region (i.e., the main surface of the single crystal Si substrate 1) which is nearly perpendicular to the flying direction of sputter particles. The same deposition can be effected also by a collimator-sputtering method or an ion evaporation method, and also in this case there will be obtained the same effects as above. (FIG. 4)

In the state of FIG. 4, a thermal treatment was conducted at 600° C. for 100 seconds in a nitrogen atmosphere. As a result, the amorphous Si film 8 present in the regions contacted with main surfaces of single-crystallized source and drain diffusion regions was polycrystallized up to a distance of 40 nm from the contact surfaces, and the amorphous Si film in all the regions contacted with the main surfaces of the source and drain regions and the lower regions of the side wall insulators also became a polycrystalline Si film 85. This crystallization could be confirmed easily by cross section observation of a separate experimental sample which has been subjected to a thermal treatment under the same conditions as above, using a transmission electron microscope. In this state, the amorphous Si film 8 remaining without being polycrystallized was removed completely with a phosphoric acid solution heated to 165° C. Under the above conditions, the etching speed for the polycrystalline silicon was about one tenth that of the amorphous silicon and finally a polycrystalline Si film 85 having a thickness of 26 nm was selectively allowed to remain in a rather raised state without becoming thin in the boundary regions with the gate side wall insulators 5. (FIG. 5)

In the state of FIG. 5, Co film was deposited on the whole surface to a thickness of 10 nm by sputtering, followed by rapid annealing at 500° C. for 60 seconds to effect silicidation. Then, unreacted Co film was removed with a mixed solution of ammonia and a hydrogen peroxide solution, allowing Co silicide film 9 to remain selectively on the exposed portions of the Si substrate and on the gate electrode 4. The thickness of the Co silicide film 9 thus formed was 26 nm approximately equal to the thickness of the selectively remaining polycrystalline Si film 85 before the silicidation. Thus, a marked difference was recognized from the thickness (about 35 nm) of Co silicide film formed under the same conditions on source-drain diffusion regions having such an impurity concentration as in the prior art. This difference indicates that in the conventional source-drain silicidation, the silicidation reaction proceeds not only in the selectively remaining Si film but also in part of the source-drain diffusion regions, while in the semiconductor device of this embodiment the silicidation of the source and drain diffusion regions 6, 7 was suppressed nearly completely. In this state, rapid thermal annealing was conducted at 800° C. to lower the Co silicide film 9 in resistance. Next, a thick Si oxide deposited film was formed on the whole surface, which surface was then planarized by mechanical-chemical polishing to afford a surface passivation insulator 10. Apertures were formed in desired area of the surface passivation insulator, then TiN film as a diffusion protection material for a metallization material and W film as a metallization material were deposited, followed by polishing for palnarization, allowing the W film to remain selectively in only the aperture. Thereafter, in accordance with a desired circuit configuration, a metal film containing aluminum as a main material was deposited and subjected to patterning, to form wiring including a drain electrode 12 and a source electrode 11. In this way there was fabricated a semiconductor device constituted mainly by NMIS. (FIG. 1)

Ultra-shallow source diffusion region 6 and drain diffusion region 7 in the NMIS fabricated through the above process steps in accordance with this embodiment and having a gate length of 50 nm were found to have a junction depth of about 10 nm and a sheet resistance of 150 Ω/□. Thus, there could be attained much more shallowing and lower resistance as compared with a junction depth of 30 nm and a sheet resistance of 400 Ω/□ as values obtained under a conventional activation treatment carried out by a rapid high-temperature thermal annealing at 1000° C. for one second. Also, the sheet resistance of the Co silicide film was 12 Ω/□ and was thus sufficiently low. A further decrease in resistance of the silicide film can be effected by setting thick the selectively remaining Si film to be silicided. A source-drain current per one μm of channel width in the MIS having a gate length of 50 nm was 0.92 mA/μm, thus indicating an improvement of more than 10% in comparison with the value in a conventional MIS of the same size. Besides, its leakage current at a gate voltage of 0V was 1 nA/μm and thus there was attained a decrease of two orders. The gate length dependence of the threshold voltage value also became smaller and it was confirmed that the NMIS having a miniaturized gate electrode length could also operate normally.

Thus, in the NMIS of this embodiment fabricated through the foregoing steps, the junction depth 10 nm of the source-drain diffusion regions is one third of that in the conventional structure, and the sheet resistance also decreased to about one third. Besides, despite the extremely shallow junction, the source-drain silicidation could be effected without causing a junction defect which is attributable to abnormal diffusion of the silicidation material. This is presumed to be the greatest factor of having realized a high current and a low leakage current. That is, the NMIS of this embodiment does not essentially require deep diffusion regions which have heretofore been used for the prevention of junction leakage, and an ultra-shallow junction could be attained. This is presumed to be the greatest factor. Although in this embodiment reference was made to the Co silicide film as an example of silicide film, the material of the metal film is not limited to Co, but there may used any of other materials so far used as silicided metal film such as, for example, Ni, Ti, Ta, W, and Mo.

### Second Embodiment

FIGS. 6 to 8 are sectional views showing fabrication steps for a PMIS which constitutes a semiconductor device according to a second embodiment of the present invention and FIG. 9 is a sectional view showing a completed state thereof. A semiconductor substrate 20 of a single crystal Si having a plane direction (100), a conductivity type of N and a diameter of 20 cm was formed with device isolation insulators 2 for defining an active region by a known method and then Sb ions were implanted so that a maximum impurity concentration of 3×10¹⁸/cm³ lied at a depth of 10 nm from a main surface of a semiconductor substrate 1 to form an abrupt buried punch-through stopper region 22 of conductive type N. As a result of the above ion implantation, the concentration of Sb at the main surface of the semiconductor substrate 1 was found to be not higher than 5×10¹⁶/cm³ which was below the sensitivity based on secondary ion mass spectroscopy. In this state, in accordance with the previous first embodiment, a gate insulator 3 was formed and also formed was a gate electrode 40 of a heavily B-doped polycrystalline Si film. Next, an 8 nm thick Si oxide film was formed at a low temperature of 400° C. by the plasma assisted deposition method and then anisotropic dry etching was performed so that the oxide film was allowed to remain selectively on only gate side walls, to form gate side wall insulators 51. In this state, using the gate electrode 40 and the gate side wall insulators 51 as implantation stopping masks, BF₂ ions were implanted under the conditions of acceleration energy 2 keV and dose 2×10¹⁵/cm² to form a high concentration impurity layer of conductive type P for both source diffusion region 61 and drain diffusion region 71. (FIG. 6)

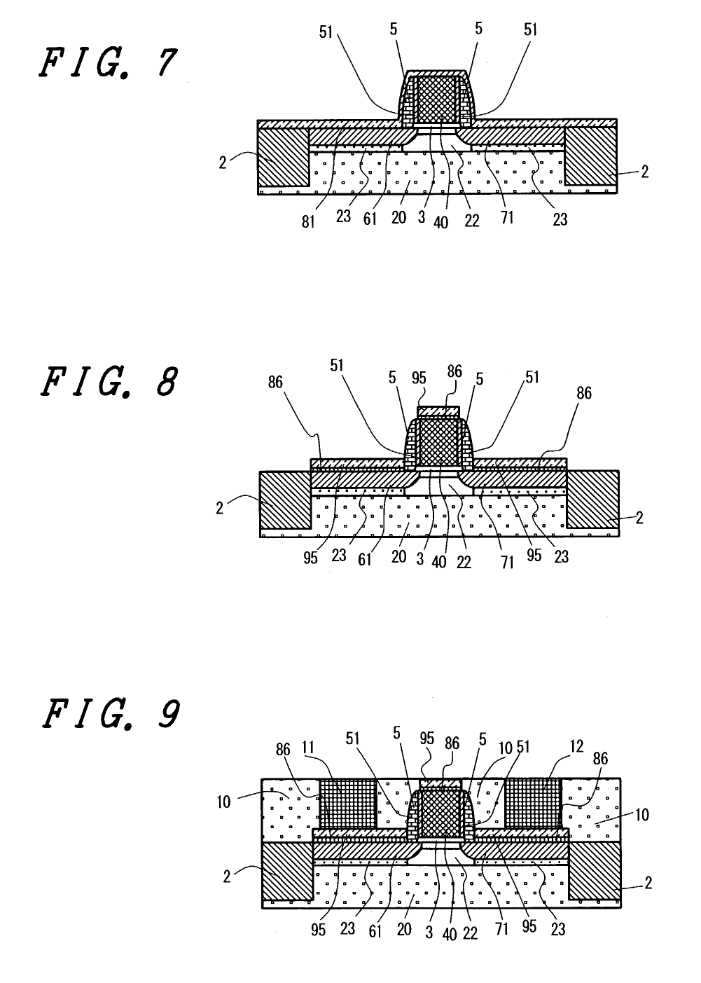

In the state of FIG. 6, a 30 nm thick Si oxide film was deposited at a low temperature of 400° C. by the plasma assisted deposition method and then anisotropic dry etching was performed so that the oxide film was allowed to remain selectively on only gate side walls, to form second gate side wall insulators 5. Subsequently, using the second gate side wall insulators 5 as implantation stopping masks, BF₂ ions of conductive type P were implanted to electrically compensate the impurity profile of the pre-formed abrupt buried punch-through stopper region 22 of conductive type N, thereby forming an intrinsic region 23. This intrinsic region is formed throughout the whole junction bottom region except gate electrode vicinities of the source diffusion region 61 and drain diffusion region 71. That is, the abrupt buried punch-through stopper region 22 of conductive type N is constituted so as to be localized in only a lower portion of a channel forming region located just under the gate electrode 40. The above ion implantation step is followed by laser irradiation under the same conditions as in the first embodiment to effect activation of the ion-implanted impurity and single-crystallization of the ion-implanted region. Subsequently, a Ge film 95 (not shown in FIG. 7) was deposited on the main surface of the semiconductor substrate to a thickness of 2 nm by the long throw sputtering method, followed by deposition of a 30 nm thick Si film within the same apparatus to form a stacked semiconductor layer 81 on the whole surface. The stacked semiconductor layer 81 is in an amorphous state throughout the whole thereof. In side face portions of the gate side wall insulators 5 parallel to the flying direction of sputter particles, the stacked semiconductor layer 81 deposited by the long throw sputtering method is only about one tenth in thickness as compared with the main surface portion of the semiconductor substrate which is perpendicular to the said flying direction. (FIG. 7)

In the state of FIG. 7, a thermal treatment was conducted at 600° C. for 100 seconds. The stacked semiconductor layer 81 present in the regions contacted with the source diffusion region 61 and the drain diffusion region 71 which had been single-crystallized on the main surface of the semiconductor substrate was polycrystallized up to a distance of 40 nm, from the contact surfaces and the lower regions of the gate side wall insulators were also polycrsytallized partially. In this state, the amorphous Si film remaining without being polycrystallized was removed completely with a phosphoric acid solution heated to 165° C. Under the above conditions, the etching speed for the polycrystalline silicon was about one tenth that of the amorphous silicon and finally a polycrystalline silicon film having a thickness of 26 nm was allowed to remain selectively in a rather raised state without becoming thin in the boundary regions with the gate side wall insulators 5. The amorphous Ge film 95 underlying the amorphous Si film is removed completely by water rinse which follows the above etching step. Subsequently, titanium (Ti) film was deposited on the whole surface to a thickness of 15 nm by sputtering, followed by heating at 650° C. for 60 seconds in a nitrogen atmosphere to form titanium silicide film 86 selectively on the exposed portions of the Si substrate and on the gate electrode 40. Then, unreacted Ti film was removed with an etching solutionn containing a hydrogen peroxide solution and thereafter a thermal treatment for the lowering of resistance was carried out at 900° C. for one second. The thickness of titanium silicide film 86 thus treated was 26 nm approximately equal to the thickness of the selectively remaining upper Si film in the stacked semiconductor layer 81 before the silicidation. Thus, a marked difference was recognized from the thickness (about 35 nm) of titanium silicide film formed under the same conditions on source-drain diffusion regions having such an impurity concentration as in the prior art. This difference indicates that in the conventional source-drain silicidation, the silicidation reaction proceeds not only in the selectively remaining Si film but also in part of the source-drain diffusion regions, while in the semiconductor device of this embodiment the silicidation of the source and drain diffusion regions 61, 71 is prevented nearly completely by the Ge film 95 having a thickness of only 2 nm. (FIG. 8)

In the state of FIG. 8, a thick Si oxide deposited film was formed on the whole surface, which surface was then planarized by mechanical-chemical polishing to afford a surface passivation insulator 10. Apertures were formed in desired area of the surface passivation insulator, then TiN film as a diffusion protection material for a metallization material and W film as a metallization material were deposited, followed by polishing for planarization, allowing the W film to remain selectively in only the aperture. Thereafter, in accordance with a desired circuit configuration, a metal film containing aluminum as a main material was deposited and subjected to patterning, to form wiring including a drain electrode 12 and a source electrode 11. In this way there was fabricated a semiconductor device constituted mainly by PMIS. (FIG. 9).

Ultra-shallow source diffusion region 6 and drain diffusion region 7 in the PMIS fabricated through the above steps in accordance with this embodiment and having a gate length of 50 nm were found to have a junction depth of about 10 nm and a sheet rsistance of 250 Ω/□. Thus, there could be attained much more shallowing and lower resistance as compared with a junction depth of 30 nm and a sheet resistance of 1.9 kΩ/□ as values obtained under a conventional activation treatment carried out by a rapid high-temperature thermal annealing at 1000° C. for one second. Also, the sheet resistance of the Ti silicide film was 10 Ω/□ and was thus sufficiently low. A further decrease in resistance of the silicide film can be effected by setting thick the selectively remaining Si film to be silicided. A source-drain current per one μm of channel width in the PMIS having a gate length of 50 nm was 0.36 mA/μm, thus indicating an improvement of more than 10% in comparison with the value in a conventional PMIS of the same size. Besides, its leakage current at a gate voltage of 0V was 1 nA/μm and thus there was attained a decrease of two orders. The above attainment of a high current is presumed to be for the following reason. The abrupt buried punch-through stopper region 22 is constituted so as to be localized in only a lower portion of a channel forming region located just under the gate electrode 40, and the impurity concentration in the channel region is not higher than 1×10¹⁷/cm³ and is thus kept extremely low, so that the degradation of mobility caused of impurity scattering is presumed to be suppressed to a satisfactory extent. Moreover, the above attainment of a low leakage current is presumed to be because the punch-through current path in the source-drain diffusion regions of an ultra-shallow junction has fully acted in the buried punch-through stopper region 22. In the PMIS of this embodiment the gate length dependence of the threshold voltage value also became smaller and it was confirmed that the PMIS having a miniaturized gate electrode length could also operate normally. Further, since most region exclusive of the gate electrode vicinity in the source-drain junction was constituted as an electrically intrinsic region, it is also possible to diminish stray capacitance and the effect of high-speed operation was obtained.

In the PMIS of the embodiment fabricated through the foregoing steps, the junction depth 10 nm of the source-drain diffusion regions is one third of that in the conventional structure, and the sheet resistance also decreased to about one eighth. Besides, despite the extremely shallow junction, the source-drain silicidation could be effected without causing a junction defect which is attributable to abnormal diffusion of the silicidation material. This is presumed to be the greatest factor of having realized a high current and a low leakage current. That is, the PMIS of this embodiment does not essentially require deep diffusion regions which have heretofore been used for the prevention of junction leakage, and an ultra-shallow junction could be attained. This is presumed to be the greatest factor.

Although in this embodiment the thin gate side wall insulators 51 are used as implantation ends in the formation of source-drain diffusion regions, this is for isolating the amorphous region formed by the implantation of a high concentration impurity from the region just under the gate electrode. More particularly, in this embodiment, for activating the impurity which constitutes the source and the drain, the amorphous region is once melted by laser irradiation to increase the solid solubility concentration of the impurity to a remarkable extent. Controlling this melted region and the gate electrode end is for preventing the possibility of short-circuit between the gate electrode and the source or the drain. It is preferable that the thickness of each of the thin gate side wall insulators 51 be equal to or smaller than the junction depth. If it is too large, a great decrease of current will result. In an ultra-miniaturized MIS having a gate length of not larger than 50 nm, it is preferable that the thickness in question be not larger than the source-drain junction depth, more preferably not larger than 10 nm.

Although in this embodiment Ti silicide film is referred to as an example of silicide film, the metal film is not limited to Ti film, but there may be used any other refractory metal film, for example, one so far used as a silicided metal film such as silicided Ni, Co, Ta, W, or Mo film. In this embodiment, moreover, the 2 nm thick Ge film could suppress the siliciding reaction of the underlying substrate for the source-drain diffusion regions. In this connection, an experiment was made using a mixed film of Ge and Si in place of the Ge film 95 as the lower film in the stacked semiconductor layer 81 to find that the same silicidation suppressing effect as above could be obtained if the ratio of Ge was not less than 20%. Thus, a mixed Ge—Si film is also employable as the silicidation suppressing film.

### Third Embodiment

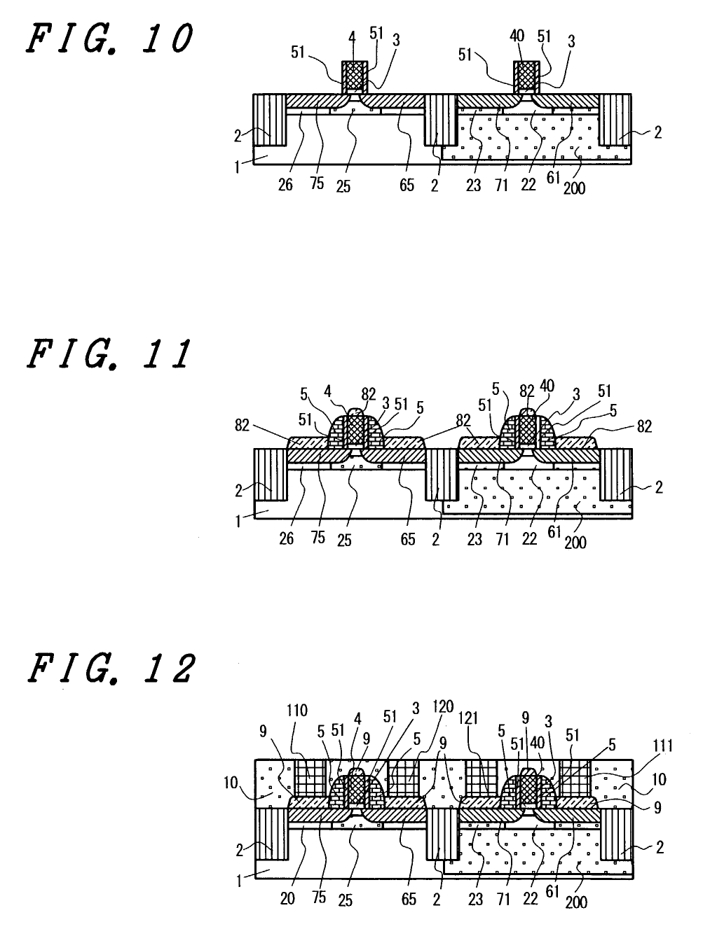

FIGS. 10 and 11 are sectional views showing fabrication steps for a CMIS which constitutes a semiconductor device according to a third embodiment of the present invention, and FIG. 12 is a sectional view showing a completed state of the CMIS. A semiconductor substrate 1 of a single crystal Si having a plane direction (100), a conductivity type of P and a diameter of 20 cm was implanted (not shown) with an impurity for adjusting the concentration of the P substrate and was formed with device isolation insulators 2 for defining a well region 200 of conductive type N and an active region in accordance with a known CMIS fabrication process. Then, in accordance with the previous second embodiment, Sb and In ions were implanted to the N well region 200 and the P substrate region, respectively, in such a manner that a maximum impurity concentration of 3×10¹⁸/cm³ lay at a depth of 10 nm from a main surface of the semiconductor substrate and that the impurity concentration in a channel region on the main surface of the semiconductor device was not higher than 1×10¹⁷/cm³, to form an abrupt buried punch-through stopper region 22 of conductive type N and an abrupt buried punch-through stopper region 25 of conductive type P. Subsequently, a gate insulator 3, a heavily doped gate electrode 4 of conductive type N, and a heavily doped gate electrode 40 of conductive type P were formed in accordance with the first embodiment. The implantation of impurity to the gate electrodes was carried out while establishing regions in accordance with a known ion implantation method. In this state, thin gate side wall insulators 51 were allowed to remain selectively in accordance with the second embodiment, and then, with the thin gate side wall insulators 51 as implantation stopping mask, Arsenic (As) ions were implanted to the P substrate region 1 and BF₂ and In ions were implanted to the N well region 200 selectively in accordance with the first embodiment, to form an N type heavily doped source region 65, a drain diffusion region 75, a P type heavily doped source region 61, and a drain diffusion region 71. All of these ions were implanted under the conditions of acceleration energy 1 keV and dose 5×10¹⁵/cm². A value of the maximum impurity concentration obtained as a result of the above condition of ion implantations was not smaller than 5×10²¹/cm³. In the above ion implantations, As ions may be substituted by P or Sb ions. As a result of the above high concentration ion implantations, the vicinities of the substrate main surface in the ion-implanted regions were all amorphized. (FIG. 10)

In the state of FIG. 10, second gate side wall insulators 5 were allowed to remain in accordance with the second embodiment. Next, using the second gate side wall insulators 5 and the gate electrodes 4 and 40 as implantation stopping masks, ion implantation was performed for electrical compensation of the abrupt buried punch-through stopping impurity regions 25 and 22. In this ion implantation, Sb of conductive type N and In of conductive type P were used in the P type region and the P type well region 200, respectively, in such a manner that their maximum impurity concentration depths became equal to maximum impurity depths in the respective punch-through stopper regions, to form electric intrinsic regions 26 and 23. In this state there was performed laser irradiation in accordance with the first embodiment to activate the implanted ions and single-crystallize the ion-implanted region. Junction depths of the conductive type N, P, ultra-high concentration source and drain diffusion regions 75, 65, 61, and 71 were determined by melting with laser irradiation and were all 10 nm. Next, by a chemical vapor reaction of monosilane (SiH₄) in a hydrogen atmosphere, a single crystal Si film 82 was allowed to grow at 600° C. selectively on the exposed conductive type N, P, ultra-high concentration source and drain diffusion regions 75, 65, 61, 71 and also on the gate electrodes 4 and 40 to the maximum thickness of 30 nm. Although the Si film 82 grew also on the gate electrodes 4 and 40, it was polycrystalline. In the selectively grown single crystal Si film 82, thickness ununiformity is formed in the boundary regions between the gate side wall insulators 5, as well as the device isolation insulators 2, and the single crystal source-drain diffusion regions due to a phenomenon called facet which is developed by the occurrence of a crystal plane (111). In the chemical vapor reaction, an impurity having the same conductivity type as the underlying source-drain diffusion regions may be implanted to the selectively grown single crystal Si film 82 at such a high concentration of 1 to 2×10²¹/cm³ or less as does not suppress the silicidation by an additional ion implantation step. In this case, an ample care must be exercised for the implantation depth in the facet region. Further, such an intentional addition of impurity as in this embodiment may be omitted. (FIG. 11)

In the state of FIG. 11 there were conducted Co film deposition and silicidation by rapid thermal annealing. By subsequent removal of unreacted Co film the selectively grown single crystal Si film 82 was converted to Co silicide film 9 completely selectively. The Co silicide film 9 thus formed had a thickness of 30 nm and was nearly coincident in shape and thickness with the selectively grown single crystal Si film 82 before silicidation. Besides, erosion by the Co silicide film 9 was not observed in the source and drain diffusion regions underlying the boundary region of the gate side wall insulators 5 with facet formed therein. Thus, a marked difference was recognized from the film thickness (about 35 nm) of Co silicide film which is formed by the application of the same conditions to source-drain diffusion regions having a conventional impurity concentration, and also from the fact that erosion by Co silicide film in the facet region has heretofore been unavoidable. This difference indicates that in the conventional source-drain silicidation, the silicidation reaction proceeds not only in the selectively grown single crystal Si film 85 but also in part of the source-drain diffusion regions, while in the semiconductor device of this embodiment not only the silicidation of the As ultra-heavily doped source-drain diffusion regions 75 and 65 of conductive type N but also the silicidation of the ultra-heavily B, In doped source-drain diffusion regions 61 and 71 of conductive type P was suppressed nearly completely. In this state, rapid thermal annealing was conducted at 800° C. to lower the Co silicide film resistance. Next, a thick Si oxide deposited film was formed on the whole surface, which surface was then planarized by mechanical-chemical polishing to afford a surface passivation insulator 10. Apertures were formed in desired area of the surface passivation insualtor, then TiN film as a diffusion barrier material for a metallization material and W film as a metallization material were deposited, followed by polishing for planarization, allowing the W film to remain selectively in only the aperture. Thereafter, in accordance with a desired circuit configuration, a metal film containing aluminum as a main material was deposited and subjected to patterning, to form wiring including drain electrodes 120, 121 and source electrodes 110, 111. In this way there was fabricated a semiconductor device constituted mainly by CMIS (FIG. 12).

Ultra-shallow source diffusion regions 75, 61 and drain diffusion regions 65, 71 in the CMIS fabricated through the above steps in accordance with this embodiment and having a gate length of 50 nm were found to have the same junction depth of about 10 nm independently of N and P conductive types. Also as to the sheet resistance, a remarkable decrease could be attained in comparison with that in the prior art despite the ultra-shallow junction. This fact indicates that the design of further miniaturization of CMIS became easier. Further, irrespective of the presence of facet in the selectively grown Si film, a stacked source-drain silicidation was effected in a completely suppressed state of erosion to the ultra-shallow source-drain diffusion regions underlying the silicide film, and the sheet resistance was also lowered to a satisfactory extent. A further decrease in resistance of the silicide film can be attained by setting thick the selectively grown single crystal Si film 82 to be silicided. Through the above improvements there could be attained a high current and a low leakage current also in the CMIS as in the first and second embodiments. The attainment of a high current is presumed to be for the following reason. The abrupt buried punch-through stopper regions 25 and 22 are localized in only lower portions of channel forming regions just under the gate electrodes 4 and 40, and the impurity concentration in the channel regions is maintained at 1×10¹⁷/cm³ or less which is extremely low, so that the degradation of mobility caused by impurity scattering was suppressed to a satisfactory extent. Moreover, the above attainment of a low leakage current is presumed to be because the punch-through current path in the source-drain diffusion regions of an ultra-shallow junction has fully suppressed by the buried punch-through stopper regions 25 and 22. In the CMIS of this embodiment the gate length dependence of the threshold voltage value also became smaller and it was confirmed that the CMIS having a miniaturized gate electrode length could also operate normally. Further, since most region exclusive of the gate electrode vicinity in the shallow source-drain junction was constituted as an electrically intrinsic region, it is also possible to diminish stray capacitance and the effect of high-speed operation was obtained.

### Fourth Embodiment

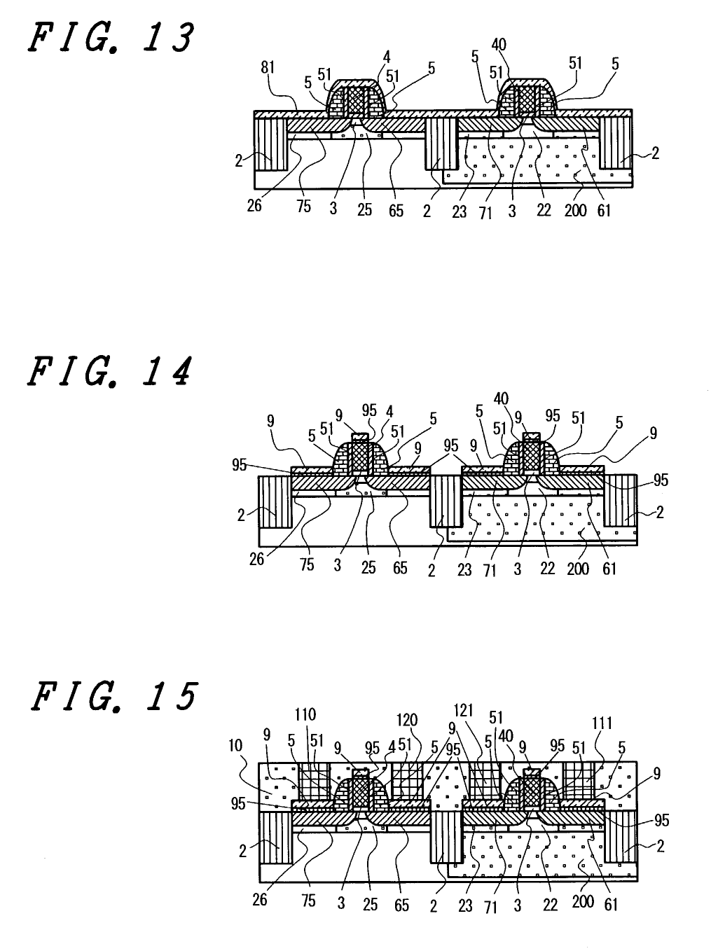

FIGS. 13 and 14 are sectional views showing fabrication steps for a CMIS which constitutes a semiconductor device according to a fourth embodiment of the present invention and FIG. 15 is a sectional view showing a completed state thereof. Fabrication step were proceeded up to the state of FIG. 10 in accordance with the third embodiment. In connection with ion implantation conditions for forming ultra-shallow source and drain diffusion regions, there was adopted in this embodiment a maximum impurity concentration of about 2×10²¹/cm³, which was as high as that in the conventional structure. In this embodiment, in the high concentration ion implantation of conductive type P, the implantation of In ions was omitted. In the state of FIG. 10 the fabrication process was proceeded in accordance with the third embodiment, but in this fourth embodiment, prior to allowing the second gate side wall insulators 5 to remain selectively, a laser irradiation step was carried out under the same conditions as in the third embodiment to activate the implanted ions and single-crystallize the ion-implanted region. Thereafter, a stacked semiconductor layer 81 was deposited on the whole surface in accordance with the second embodiment. In this fourth embodiment, instead of Ge film 95, a mixed film comprising 20% Ge and 80% Si was used as an underlying film. The underlying film may be Ge film alone because it acts as a silicidation suppressing film if the ratio of Ge is 20% or more. (FIG. 13)

In the state of FIG. 13, the stacked semiconductor layer 81 in the regions contacted with the source diffusion regions 61, 75 and the drain diffusion regions 71, 65 which had been single-crystallized on the main surface of the semiconductor substrate in accordance with the second embodiment was polycrystallized and the amorphous Si film and the underlying amorphous Ge film 95, remaining without being polycrystallized, were removed completely to afford a selectively remaining polycrystalline Si film 85. Then, in accordance with the first embodiment, there were conducted sputtering of Co film and subsequent thermal treatment and removal of unreacted Co film, thereby allowing Co silicide film 9 to remain on the Si substrate exposed portions of the source-drain diffusion regions 61, 75, 71, and 65 and also on the gate electrode 4. The thickness of the Co silicide film 9 thus formed was 26 nm approximately equal to the thickness of the selectively remaining polycrystalline Si film 85 before the silicidation. Thus, a marked difference was recognized from the thickness (about 35 nm) of Co silicide film formed under the same conditions on source-drain diffusion regions having a conventional impurity concentration. This difference indicates that in the conventional source-drain silicidation, the silicidation reaction proceeds not only in the selectively remaining Si film but also in part of the source-drain diffusion regions, while in the semiconductor device of this embodiment the silicidation of the source and drain diffusion regions 61, 76, 71, and 65 was suppressed almost completely. (FIG. 14)

In this state, rapid thermal annealing was conducted at 800° C. to render the Co silicide film 9 low in resistance. Next, a thick Si oxide deposited film was formed on the whole surface, which surface was then planarized by mechanical-chemical polishing to afford a surface passivation insulator 10. Apertures were formed in desired area of the surface passivation insulator, then TiN film as a diffusion barrier material for a metallization material and W film as a metallization material were deposited, followed by polishing for planarization, allowing the W film to remain selectively in only the aperture. Thereafter, in accordance with a desired circuit configuration, a metal film containing aluminum as a main material was deposited and subjected to patterning, to form wiring including drain electrodes 120, 121 and source electrodes 110, 111. In this way there was fabricated a semiconductor device constituted mainly by CMIS (FIG. 15).

Ultra-shallow source diffusion regions 75, 61 and drain diffusion regions 65, 71 in the CMIS fabricated through the above steps in accordance with this embodiment and having a gate length of 50 nm were found to have the same junction depth of about 10 nm independently of N and P conductive types. Also as to the sheet resistance, there could be attained a remarkable decrease as compared with that in the prior art despite the ultra-shallow junction. This fact indicates that the design of further miniaturization of CMIS became easier. Further, by the action of an SiGe silicidation suppressing film 95, a stacked source-drain silicidation was effected in a completely suppressed state of erosion to the ultra-shallow source-drain diffusion regions underlying the silicide film, and the sheet resistance was also lowered to a satisfactory extent. Through the above improvements there could be attained a high current and a low leakage current also in the CMIS as in the third embodiment. The attainment of a high current is presumed to be for the following reason. The abrupt buried punch-through stopper regions 25 and 22 are localized in only lower portions of channel forming regions just under the gate electrodes 4 and 40, and the impurity concentration in the channel regions is maintained at 1×10¹⁷/cm³ or less which is extremely low, so that the degradation of mobility caused by impurity scattering was suppressed to a satisfactory extent. Moreover, the above attainment of a low leakage current is presumed to be because the punch through current path in the source-drain diffusion regions of an ultra-shallow junction has fully suppressed by the buried punch-through stopper regions 25 and 22. In the CMIS of this embodiment the gate length dependence of the threshold voltage value also became smaller and it was confirmed that the CMIS having a miniaturized gate electrode length could also operate normally. Further, since most region exclusive of the gate electrode vicinity in the shallow source-drain junction was constituted as an electrically intrinsic region, it is also possible to diminish stray capacitance and the effect of high-speed operation was obtained.

### Fifth Embodiment

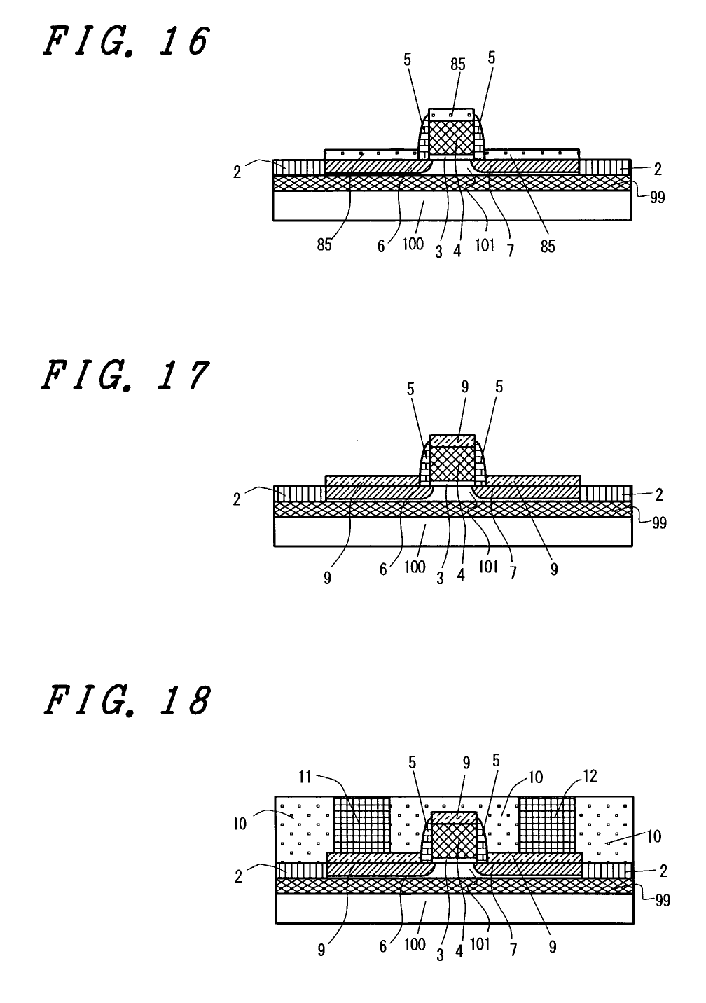

FIGS. 16 and 17 are sectional views showing fabrication steps for an NMIS which constitutes a semiconductor device of a fifth embodiment of the present invention and FIG. 18 is a sectional view showing a completed state thereof. In this embodiment as a semiconductor substrate for fabricating the NMIS there was used a single crystal Si substrate called SOI (silicon on insulator), having a diameter of 20 cm and serving as a thin single crystal semiconductor film 101, in which a region for constitutiting a semiconductor device is completely separated from a supporting substrate 100 through a buried oxide film 99. The thin single crystal semiconductor film 101 had a plane direction (100), a conductivity type of P, and an initial thickness of 100 nm prior to start of a fabrication process. Its thickness was controlled by thermal oxidation and removal of the thin single crystal semiconductor film 101 so as to finally become 20 nm at a completed stage of the fabrication process. As the thin single crystal semiconductor film 101, a single crystal silicon is in wide use, but it is not necessary to make limitation to a single crystal silicon. There also may be used a single crystal SiGe which is a mixed crystal of Si and Ge, a stacked structure of a single crystal Si and a single crystal SiGe, or a single crystal Ge. In this embodiment, an NMIS was fabricated in accordance with the first embodiment. In this embodiment, a source diffusion region 6 and a drain diffusion region 7 both having an ultra-shallow junction are amorphized up to a depth of 10 nm by the implantation of ultra-high concentration As ions, not reaching a buried oxide film 99. There is ensured a state in which a single crystal region serving a crystal growth nucleus in impurity activation by laser irradiation and a thermal treatment for single-crystallization for both source and drain diffusion regions 6, 7 underlies the amorphous region. Therefore, the source diffusion region 6 and the drain diffusion region 7 are single-crystallized, not polycrystallized. In the case where the amorphizing by the high concentration ion implantation reaches the buried oxide film 99, the crystal growth nucleus lies in only the single crystal region underlying a gate electrode 4 for which ion implantation is suppressed, and thus the crystal growth becomes a lateral growth, so that the lateral crystal growth rate at such an ultra-thin film of 20 nm is extremely low and there proceeds polycrystallization. Consequently, in the source and drain diffusion regions which are in a polycrystalline state, a great increase of sheet resistance results, thus leading to an increase in series resistance of MIS and obstruction to the attainment of a high current. This is not preferable. According to the construction of the NMIS of this embodiment it is possible to suppress an increase in series resistance of source and drain regions. Fabrication steps up to the formation of a selectively remaining polycrystal Si film 85 are carried out in accordance with the first embodiment.(FIG. 16)

In the state of FIG. 16, Co film was deposited on the whole surface and the selectively remaining polycrystal Si film 85 was silicided. Then, unreacted Co film was removed with a mixed solution of ammonia and a hydrogen peroxide solution, allowing Co silicide film 9 to remain selectively on the exposed portions of the source and drain diffusion regions 6, 7 and also on the gate electrode 4. The Co silicide film 9 thus formed did not erode the interior of the source and drain diffusion regions 6, 7, thus presenting a marked difference from the conventional situation where erosion to source-drain diffusion regions having a conventional impurity concentration has been unavoidable. This difference indicates that in the conventional source-drain silicidation, the silicidation reaction proceeds not only in the selectively remaining polycrystal Si film but also in part of the source-drain diffusion regions, while in the semiconductor device of this embodiment the silicidation of the source-drain diffusion regions 6, 7 was suppressed nearly completely due to the presence of an ultra-high concentration As. (FIG. 17)

In the state of FIG. 17, rapid thermal annealing was conducted at 800° C. to lower the Co silicide film 9 resistance. Next, a thick Si oxide deposited film was formed on the whole surface, which surface was then planarized by mechanical-chemical polishing to afford a surface passivation insulator 10. Apertures were formed in desired area of the surface passivation insulator, the TiN film as as a diffusion barrier material for a metallization material and W film as a metallization material were deposited, followed by polishing for planarization, allowing the W film to remain selectively in only the aperture. Thereafter, in accordance with a desired circuit configuration, a metal film containing aluminum as a main material was deposited and subjected to patterning, to form wiring including a drain electrode 12 and a source electrode 11. In this way there was fabricated a semiconductor device constituted mainly by NMIS. (FIG. 18)

The NMIS of this embodiment faricated through the above fabrication steps and having a gate length of 50 nm had source and drain diffusion regions of an ultra-shallow junction with a single crystallinity retained on th ultra-thin SOI substrate, and the thickness of the thin single crystal semiconductor film 101 is sufficiently thin in comparison with the gate electrode length. With this construction, in the NMIS of this embodiment, an electric field of the gate is applied to the whole of the thin single crystal semiconductor film even without setting high the substrate impurity concentration in the channel region and the underlying region, whereby the punch-through path can be fully cut off. That is, according to this embodiment, the implantation of a punch-through stopping impurity is not required and it is possible to attain a high current and low stray capacitance of MIS, i.e., both high-speed operation and reduction of fabrication steps. For unnecessitating the implantation of a punch-through stopping impurity it is absolutely necessary that the thin single crystal semiconductor film 101 be an ultra-thin film. In a miniaturized MIS, it is preferable that the thickness in question be not larger than the gate length, more preferably, not larger than one third of the gate length.

According to the present invention, in an ultra-miniaturized MIS, there can be attained a structure which does not require deep source and drain diffusion regions and wherein, in connection with source and drain diffusion regions, the portion underlying a main surface of a single crystal semiconductor substrate is constituted by only diffusion regions having an ultra-shallow junction and a low resistance, while in the portion overlying the main surface of the single crystal semiconductor substrate, a silicided metal film acting on the lowering of resistance is disposed selectively on the source and drain diffusion regions. Therefore, the problem of a punch-through leakage current and a tunnel leakage current both based on deep source-drain diffusion regions is essentially eliminated and there can be attained a low leakage current, i.e., a low power consumption, despite the ultra-miniaturized MIS. Moreover, the ion implantation step related to the fabrication of deep source-drain diffusion regions and the lithography step related to establishing an ion implantation region become unnecessary, thus bringing about the effect of reducing the number of fabrication steps, lowering a defect yield and reducing the process cost.

According to the present invention, a silicided metal film stacked on source-drain diffusion regions can be formed in a self alignment relation to the selectively remaining semiconductor film to be silicided, and erosion to the underlying ultra-shallow source-drain junction can be prevented self-alignly, whereby such a defect as junction destruction can be eliminated completely.

Further, according to the present invention, in a semiconductor layer stacked on source-drain diffusion regions by a selective epitaxial method, there can be obtained an effect of essentially eliminating the conventional problem of the occurrence of facet and substrate erosion of a silicided metal film caused by silicidation thereof and omitting an extra addition of a fabrication step related to a countermeasure to facet.

Main reference numerals will be explained below for facilitating the understanding of the drawings.

1: semiconductor substrate

2: isolation insulator

3: gate insulator

4, 40: gate electrode

5, 51: gate side wall insulator

6: ultra-heavily doped, shallow junction, source diffusion region

7: ultra-heavily doped, shallow junction, drain diffusion region

8: amorphous semiconductor film

81: stacked semiconductor layer

82: selective epitaxial semiconductor film

83: polycrystal semiconductor film

9, 86: silicided metal film

95: silicidation suppressed semiconductor film

10: surface passivation insulator

11: source electrode

12: drain electrode

What is claimed is:

1. A method of fabricating a semiconductor device including a second conductive type field effect transistor, said field effect transistor having a gate electrode formed on a first conductive type semiconductor substrate through a gate insulator and also having a pair of second conductive type semiconductor regions formed on both sides of said gate electrode on said semiconductor substrate, said method comprising:
a first step of setting a second conductive type impurity concentration of at least a partial surface area of said semiconductor region to a value of not smaller than 5×10²¹/cm³;
a second step of partially exposing the surface area for which the impurity concentration has been set;
a third step of forming silicon film on the exposed surface area;
a fourth step of forming a refractory metal film on said silicon film; and
a fifth step of siliciding said refractory metal film by a thermal treatment.

2. A method according to claim 1, wherein ion implantation of a second conductive type impurity to said semiconductor substrate, using said gate electrode as mask, and a thermal treatment for activating the implanted second conductive type impurity, are performed in said first step.

3. A method according to claim 2, wherein said second conductive type impurity is any of As (arsenic), P (phosphorus), In (indium), and Sb (antimony).

4. A method according to claim 1, wherein all of said silicon film is replaced to silicide film in said fifth step.

5. A method according to claim 1, wherein said refractory metal film is any of cobalt film, nickel film, titanium film, tantalum film, tungsten film, and molybdenum film.

6. A method of fabricating a semiconductor device, said semiconductor device having a pair of second conductive type semiconductor regions formed on a first conductive type semiconductor substrate and a gate electrode formed on said semiconductor substrate through a gate insulator at a position opposed to a portion sandwiched by both said second conductive type semiconductor regions, said method comprising:
a first step of partially exposing surfaces of said semiconductor regions;
a second step of forming a semiconductor film containing not less than 20 weight percent of Ge (germanium) on the exposed surfaces of the semiconductor regions;
a third step of forming a silicon film on said semiconductor film;
a fourth step of forming a refractory metal film on said silicon film; and
a fifth step of siliciding said refractory metal film by a thermal treatment.

7. A method according to claim 6, wherein said semiconductor film is either an alloy film of germanium and silicon or germanium film.

8. A method according to claim 6, wherein all of said silicon film is replaced to silicide film in said fifth step.

9. A method according to claim 6, wherein said refractory metal film is any of cobalt film, nickel film, titanium film, tantalum film, tungsten film or molybdenum film.

10. A method according to claim 6, wherein ion implantation of a second conductive type impurity to said semiconductor substrate, using said gate electrode as mask, and a thermal treatment for activating the implanted second conductive type impurity, are performed prior to said first step to form said semiconductor regions.

11. A semiconductor device having a second conductive type field effect transistor formed on a main surface of a first conductive type semiconductor substrate, said semiconductor device comprising:
a gate insulator formed on said first conductive type semiconductor substrate;
a gate electrode formed on said gate insulator;
second conductive type source/drain regions formed on the main surface side in said semiconductor substrate; and
a refractory metal silicide film formed on each of said source/drain regions,
wherein the concentration of a second conductive type impurity at portions of said source/drain regions which portions are in contact with said refractory metal silicide film is not lower than 5×10²¹/cm³.

12. A semiconductor device according to claim 11, wherein said second conductive type impurity is any of arsenic, phosphorus, indium, and antimony.

13. A semiconductor device according to claim 11, wherein said refractory metal silicide film is any of cobalt silicide film, nickel silicide film, titanium silicide film, tantalum silicide film, tungsten silicide film, and molybdenum silicide film.

14. A semiconductor device comprising:
a first conductive type well region formed within a semiconductor substrate;
second conductive type source region and drain region formed in said well region;
a gate electrode formed through a gate insulator on said well region located between said source and drain regions;
a semiconductor film formed on said source region or said drain region and containing not less than 20% of germanium; and
a refractory metal silicide film formed on said semiconductor film.

15. A semiconductor device according to claim 14, wherein said semiconductor film is either an alloy film of germanium and silicon or germanium film.

16. A semiconductor device according to claim 14, wherein said refractory metal silicide film is any of cobalt silicide film, nickel silicide film, titanium silicide film, tantalum silicide film, tungsten silicide film, and molybdenum silicide film.
